(19) United States
(12) Patent Application Publication
(10) Pub. No.: US 2008/0087890 A1
(43) Pub. Date: Apr. 17, 2008

(54) Methods to form dielectric structures in semiconductor devices and resulting devices

(75) Inventors: Kie Y. Ahn, Chappaqua, NY (US); Leonard Forbes, Corvallis, OR (US)

Correspondence Address: SCHWEGMAN, LUNDBERG & WOESSNER, P.A., P.O. BOX 2938, MINNEAPOLIS, MN, 55402, US

(73) Assignee: Micron Technology, Inc.

(21) Appl. No.: 11/581,675

(22) Filed: Oct. 16, 2006

(51) Int. Cl. H01L 29/78; H01L 21/473

(52) U.S. Cl. 257/43; 438/785; 438/3; 438/591; 438/104; 257/295

(57) ABSTRACT

Methods of forming dielectric structures with a high dielectric constant (high “k”) may be used to fabricate gate dielectrics in integrated circuits and in other devices such as spintronic devices. A dielectric structure may be formed by atomic layer deposition of separate layers of zirconium oxide, hafnium oxide, and titanium oxide onto a substrate surface, or it may be formed as a composite layer by a high temperature treatment, such as furnace annealing.

### TECHNICAL FIELD

This application, in a number of embodiments, relates generally to semiconductor devices and device fabrication, including dielectric structures and their method of fabrication.

### BACKGROUND

A market-driven need exists to continue to reduce the size of electronic devices containing semiconductor devices in order to obtain lower power consumption, lower operating voltages and higher performance. Smaller electronic devices typically reduce transistor size to obtain improved performance, which may entail reducing the thickness of the gate dielectric (typically silicon dioxide, SiO₂) in proportion to the shrinkage of the gate length. For example, a metal-oxide-semiconductor field effect transistor (MOSFET) might have a 1.5 nm thick SiO₂ gate dielectric for a gate length of 70 nm. Smaller, more reliable integrated circuits (ICs) may be used in products such as processor chips, mobile telephones, games, displays and memory devices, such as dynamic random access memories (DRAMs).

Another method of improving IC devices may include the use of what may be known as “ferroelectric devices” for non-volatile memory devices, and the use of ferro-magnetic semiconductors in forming what may be known as “spintronic devices”. Conventional electronic devices may rely upon the transport of electrons over conductors to form signals. Spintronic devices may exploit the spin of the electrons to form smaller, more robust and more versatile devices that may be more resistant to outside interference than other electronic devices. Electrons may have a property known as “spin”, which refers to the direction of the spin axis of the particle, which may be either spin-up or spin-down. When the electron spins within a group of electrons in a conductor are all aligned (i.e., either essentially all spin-up or all spin-down), they may create a large scale net magnetic moment. The aligned electron spins may create an analog to the situation found in a conventional magnetic material, such as the ferromagnetic elements iron and cobalt, wherein an application of a strong external magnet field can cause all of the spins of the iron or cobalt atoms to align and form a permanent magnet.

Since about 1988, spintronic devices have been known following the discovery of the principle of giant magneto-resistance (GMR), which causes relatively large changes in electrical resistance in ultrathin magnetized layers under an applied external magnetic field. This discovery resulted in the design of magnetic memory devices with small magnetic regions that are sensitive to small magnetic fields, and magnetic disks that could hold up to twenty times the amount of data as previous magnetic disks. By flipping the impressed magnetization of the ultra-thin layers, spintronic devices may also be operated as switches that may be used to form random access memory (RAM) devices similar to semiconductor memories such as DRAMs, but with the advantage of being non-volatile. Such magnetic RAMs may be called “MRAMs”, which may be smaller, faster, and cheaper, use less power and be more resistant to high temperatures and high radiation levels than other memories.

Spintronic devices may also be used as tunnel diodes having electrons that tunnel from a magnetic layer through an ultra thin insulating metal oxide layer to another magnetic layer. The electrons tunnel only when the magnetization alignments of the two magnetic layers are in the same direction. The amount of relative tunneling current may depend upon the width of what is known as the “bandgap” of the metal oxide layer, as well as upon the physical thickness of the metal oxide layer. Such layers may include cobalt doped rutile crystals.

The semiconductor industry has relied upon reducing the dimensions of basic devices, for example the silicon based MOSFET, by a process that may be known as “scaling”. Device scaling may include scaling the gate dielectric, which has primarily been fabricated of silicon dioxide. A thermally grown amorphous SiO₂ layer may provide an electrically and thermodynamically stable material, where the interface of the SiO₂ layer with the underlying silicon may have a high quality charge state and good electrical isolation properties. However, increased scaling in microelectronic devices has demonstrated the potential benefits of using other dielectric materials as gate dielectrics, in particular dielectrics with higher dielectric constants to replace the use of various combinations of silicon dioxide SiO₂, silicon nitride Si₃N₄ and silicon oxynitride SiON. For higher dielectric constant materials (high “k”) to be practical, they may have the properties of high permittivity, thermal stability, high film and surface quality and smoothness, low hysteresis, low leakage current density, and long-term reliability. High k films may be metal oxide unary materials such as Al₂O₃, CeO₂, TiO₂, HfO₂ and ZrO₂, which have a single component, or they may be binary systems such as (Y₂O₃)ₓ(ZrO₂)_{1-X}, LaAlO₃, and (HfO₂)(Al₂O₃), which have two components, or they may be ternary systems having three components such as (HfO₂) (ZrO₂) (SnO₂), and so on. High k films may be single layers, or they may be formed of multiple layers of different materials that act as a composite material. A high k dielectric may be amorphous to maintain surface smoothness and prevent electric field concentration at sharp projections (asperities), and to minimize leakage current along crystal boundaries.

### BRIEF DESCRIPTION OF THE DRAWINGS

FIG. 1 depicts an atomic layer deposition system for forming a layer of zirconium oxide, hafnium oxide, and titanium oxide layers, according to various embodiments;

FIG. 2 illustrates a flow diagram of a method to form a layer by atomic layer deposition according to various embodiments;

FIG. 3 illustrates a transistor containing a layer deposited according to various embodiments;

FIG. 4 illustrates a capacitor containing a dielectric layer deposited according to various embodiments;

FIG. 5 is a simplified diagram of a controller coupled to an electronic device, according to various embodiments; and

FIG. 6 illustrates a diagram of an electronic system having at least some devices with a dielectric film formed according to various embodiments.

### DETAILED DESCRIPTION

A gate dielectric in a transistor may have both a physical gate dielectric thickness and an equivalent oxide thickness (EOT or t_{eq}). The equivalent oxide thickness (EOT) quantifies the electrical properties, such as capacitance, of the high k gate dielectric in terms of a representative physical thickness of a silicon dioxide gate dielectric. The term t_{eq} may be defined as the thickness of a theoretical SiO₂ layer that may have the same capacitance density as a given dielectric.

A SiO₂ layer deposited on a Si surface as a gate dielectric may have a t_{eq} larger than its physical thickness, t. This t_{eq} results from the capacitance in the surface channel upon which the SiO₂ is deposited, due to the formation of a depletion/inversion region. The depletion/inversion region may result in t_{eq} being from 3 to 6 Angstroms (Å) larger than the physical SiO₂ thickness, t. With the semiconductor industry moving to scale the gate dielectric equivalent oxide thickness to less than 10 Å, the physical thickness for a SiO₂ layer used for a gate dielectric may be approximately 4 to 7 Å.

Additional features for a SiO₂ gate dielectric layer may depend upon the properties of the gate electrode used in conjunction with the SiO₂ gate dielectric. Using a conventional polysilicon gate may result in an additional increase in t_{eq} for the SiO₂ layer. The additional t_{eq} value may be reduced by using a metal gate electrode, although metal gates are not typically used in typical complementary metal-oxide-semiconductor (CMOS) field effect transistor technology. Thus, future devices may have a physical SiO₂ gate dielectric layer of about 5 Å or less. Such a thin SiO₂ oxide layer may create current leakage issues across the thin oxide.

Silicon dioxide may be commonly used as a gate dielectric, in part, due to its electrical isolation properties in a SiO₂—Si based structure. This electrical isolation may be due to the relatively large bandgap of SiO₂ (8.9 eV) resulting in a relatively good electrical insulator. Significant reductions in bandgap value below SiO₂ reduce the utility of a material for use as a gate dielectric. However, as the thickness of a SiO₂ layer decreases, the number of atomic layers, or monolayers of the material in the layer typically decreases. At some thickness, the number of monolayers may be so small that the SiO₂ layer may not have as complete an arrangement of atoms as found in a thicker, or bulk, layer. As a result of incomplete formation relative to a bulk structure, a thin SiO₂ layer of only one or two monolayers may fail to form a full band gap. The lack of a full bandgap in a SiO₂ gate dielectric may cause an effective short between an underlying conductive silicon channel and an overlying conductive gate. This undesirable property tends to limit the minimum physical thickness to which a SiO₂ layer may be scaled, and it is thought to be about 7-8 Å. Therefore, for future devices to have a t_{eq} less than about 10 Å, dielectrics other than SiO₂ may be considered for use as a gate dielectric.

For a dielectric layer used as a gate dielectric, the capacitance may be determined as in a parallel plate capacitance: C=kε₀A/t, where k is the dielectric constant, ε₀ is the permittivity of free space, A is the area of the capacitor, and t is the thickness of the dielectric. The thickness, t, of a material may be related to its t_{eq} for a given capacitance, with SiO₂ having a dielectric constant kₒₓ=3.9, as

t=(k/kₒₓ)t_{eq}=(k/3.9)t_{eq}.

Thus, materials with a dielectric constant greater than that of SiO₂ (typically about 3.9) may have a physical thickness considerably larger than a desired t_{eq}, while providing the desired equivalent oxide thickness. For example, an illustrative dielectric material with a dielectric constant of 10, such as aluminum oxide Al₂O₃, may have a thickness of 25.6 Å to provide a t_{eq} of 10 Å. Thus, a reduced equivalent oxide thickness for transistors may be realized by using dielectric materials with higher dielectric constants than SiO₂.

As noted above, an equivalent oxide thickness for lower transistor operating voltages and smaller transistor dimensions may be realized by using materials having a higher dielectric constant. However, additional fabricating issues may make determining a suitable replacement for SiO₂ difficult. If the use of silicon-based devices continues, then potentially significant constraints on the substitute dielectric material may occur. During the formation of the dielectric on the silicon layer, there exists the possibility that a small layer of SiO₂ may be formed in addition to the desired dielectric. The electrical result may comprise a dielectric layer having two sub-layers connected to each other and to the silicon layer on which the dielectric is formed. In such a case, the resulting capacitance would be that of two dielectrics in series. Thus, the t_{eq} of the dielectric layer may be considered as the sum of the SiO₂ thickness and a multiplicative factor of the thickness t of the dielectric being formed, written as

t_{eq}=t_{SiO2}+(kₒₓ/k)t.

If a SiO₂ layer is formed in the process of forming the high k dielectric, the t_{eq} may again be limited by the SiO₂ layer. Thus, a useful property of a high k dielectric may be an oxygen barrier to prevent a layer of SiO₂ from forming on the silicon surface. The layer directly in contact with the silicon layer may provide a high quality interface for high channel carrier mobility and low surface charge density.

One of the advantages of using SiO₂ as a gate dielectric may be that the formation of the SiO₂ layer may result in an amorphous gate dielectric. An amorphous structure for a gate dielectric may provide reduced leakage current problems associated with grain boundaries in polycrystalline gate dielectrics, sometimes implicated in high current leakage paths. Crystal grain size and orientation changes throughout a polycrystalline gate dielectric may cause variations in the film's dielectric constant, along with uniformity and surface topography issues. Materials having a high dielectric constant relative to SiO₂ may also have the disadvantages of a crystalline form, and they may have a lower bandgap width.

Another consideration for selecting the material and method for forming a dielectric film for use in electronic and spintronic devices may be the roughness of the dielectric film on a substrate. Surface roughness may have a significant effect on the electrical properties of the gate oxide and on the resulting operating characteristics of the transistor. The leakage current through a physical 1.0 nm gate dielectric may increase by a factor of 10 for every 0.1 increase in the root-mean-square (RMS) roughness of the dielectric layer. Such surface damage may occur during a conventional sputtering deposition process, when particles of the material to be deposited may bombard the surface at a high energy. When a sputtered particle hits the surface, some particles may adhere, and other particles may cause surface damage by knocking out a portion of the surface layer creating pits. The surface of such a deposited dielectric layer may have a rough contour due to the rough interface at the body region, and thus the electrical properties of a thin film may not be as good as the values in a bulk sample of the same material. Thus the method used to form the thin film dielectric may have a substantial impact on the usefulness of the material in electronic devices. Atomic layer deposition (ALD) may provide a dielectric layer with superior surface uniformity and thickness control than other deposition methods. The use of ALD may result in a dielectric layer grown on silicon having surface smoothness of about 0.20 nm root mean square (RMS) value on a 20 nm thick layer, which may result in less electric field concentration at insulator corners and projections, and lower leakage currents.

Titanium oxide has a dielectric constant of 30-35, an electronic bandgap of about 5.0 eV and an optical bandgap of about 3.10 in a crystal form. Zirconium oxide has a dielectric constant of 18-23, a bandgap of about 6.0 eV, and an optical bandgap of about 3.16 eV in a 50% combination with titanium oxide crystals. Hafnium oxide has a dielectric constant of 17-22, a bandgap of about 5.6 eV, and an optical bandgap of about 3.28 eV in a 50% combination with titanium oxide crystals. Mixing hafnium and zirconium in doped titanium oxide may allow an optical bandgap as high as 3.30 eV, although the crystalline nature of the titanium oxide may suffer at doping levels of zirconium above 35%, or of hafnium above 25%. A maximum realistic optical bandgap of about 3.26 eV may be found at a zirconium doping level of 10% and a hafnium doping level of 18%, which may then have a total zirconium level of 72% in the crystal. It may be useful to provide spintronic devices having crystalline films with an adjustable optical band gap that may be controllably varied from 3.15 to 3.26 eV.

In high k dielectrics for transistor gate dielectrics, which as noted above may be beneficially amorphous, hafnium oxide may have a conduction band/valence band offset versus that of silicon of 2.0 eV/2.5 eV, which may be useful in reducing leakage currents. However, hafnium oxide may lose its amorphous nature at temperatures of about 500° C., which is a temperature below that found in typical MOS processes that may follow the gate dielectric deposition. Another issue with layers containing hafnium oxide is that oxygen may diffuse through the hafnium oxide during subsequent furnace operations, which may form a SiO₂ layer underneath the hafnium oxide at the silicon interface. This may result in reduced capacitive coupling between the gate electrode and the semiconductor. Zirconium oxide containing layers may have improved thermal stability as compared to hafnium oxide alone, and zirconium oxide containing layers may have superior silicon interface properties since the atomic size of zirconium may match hafnium atoms better than titanium. The resulting three part structure of titanium, hafnium, and zirconium oxides may remain amorphous through the thermal cycles of typical semiconductor processing up to 900 to 1,000° C., due to the zirconium content, and the dielectric constant may still be higher than 25 due to the high k of the titanium oxide portion of the layer. Current leakage across the dielectric may range between 10⁻⁷ A/cm² to 10×10⁻⁹ A/cm², depending upon the composition, and it may form useful dielectric layers for semiconductor device gate insulators. The optical band gap may be varied from the low of titanium oxide crystals, to the high of zirconium oxide doped crystals by varying the composition, and thus the ternary oxide may be useful in spintronic devices. ALD deposition may have composition control superior to other deposition methods and may more uniformly select and control the material band gap, which may be useful in spintronic devices, for example by doping titanium oxide layers with hafnium and zirconium to obtain a ferromagnetic crystalline material.

Forming such films using atomic layer deposition can enable controlling transitions between different material layers. As a result of such control, ALD deposited dielectric films may have an engineered transition with a substrate surface, or they may be formed of many thin layers of different dielectric materials to enable selection of the dielectric constant to a value that is between the values obtainable from pure dielectric compounds.

ALD is a modification of chemical vapor deposition (CVD) and may also be called “alternatively pulsed-CVD”. In ALD, chemical precursors may be introduced one at a time to the substrate surface mounted within a reaction chamber (or reactor). This introduction of chemical precursors may take the form of pulses of each precursor. The precursor is made to flow into a specific area or region for a short period of time. Between the pulses, the reaction chamber may be purged with a gas, which may be an inert gas, and/or the chamber may be evacuated. ALD may occur at atmospheric pressure or in relatively high vacuum levels.

In the first reaction of the ALD process, the first precursor may saturate and may be chemisorbed (or adsorbed) onto the substrate surface during the first pulsing phase. Subsequent pulsing with a purging gas may remove non-chemisorbed precursor from the reaction chamber.

A second pulsing phase may introduce a second precursor (which may be referred to as a “reactant”) to the substrate where the growth reaction of the desired film may take place, with a reaction thickness that may depend upon the amount of chemisorbed first precursor. Subsequent to the film growth reaction, reaction byproducts and precursor excess may be purged or evacuated from the reaction chamber. A precursor chemistry, having precursors that adsorb and aggressively react with each other on the substrate, may enable one ALD cycle to be performed in less than one second in a flow type reaction chamber. Precursor pulse times may range from about 0.3 sec to 3 seconds.

In ALD processes, the saturation of all the reaction and purging phases may make the film growth self-limiting. Self-limiting growth may result in large area uniformity and conformality, having applications in such cases as planar substrates, filling deep trenches, and in the processing of porous silicon and high surface area silica and alumina powders. ALD may operate to control film thickness in a straightforward manner by controlling the number of growth cycles.

Precursors used in an ALD process may be gaseous, liquid or solid, however, liquid or solid precursors may be volatile with a vapor pressure high enough for effective mass transportation. Solid precursors and liquid precursors may work better when heated and introduced through heated tubes to the substrates. An adequate vapor pressure may be reached at a temperature that is below the substrate temperature to minimize condensation of the precursors on the substrate. The self-limiting growth mechanisms of ALD may allow relatively low vapor pressure solid precursors to be used, though evaporation rates may vary during processing because of changes in solid surface area.

The precursors used in ALD may be thermally stable at the substrate temperature since precursor decomposition may destroy surface control and the advantages of the ALD method, which may rely upon the reaction of the precursor at the substrate surface. A slight decomposition, if slow compared to the ALD growth rate, may be tolerated. The precursors may chemisorb on, or react with, the surface. The molecules at the substrate surface may react aggressively with the second precursor, which may be called a reactant, to form the solid film. Precursors should not react substantially with the formed film to cause etching, and precursors should not dissolve substantially in the film. The ability to use highly reactive precursors in ALD may contrast with the selection of precursors for conventional CVD type reactions. The by-products in the reaction may be gaseous in order to allow their removal from the reaction chamber during a purge stage. Further, it may be useful if the by-products do not react or adsorb on the surface.

In an ALD process, the self-limiting process sequence may involve sequential surface chemical reactions. ALD may rely upon chemistry between a reactive surface and one or more reactive molecular precursors, which may be pulsed into the ALD reaction chamber separately. The metal precursor reaction at the substrate may be followed by an inert gas pulse (or purge) to remove a precursor and by-products from the reaction chamber prior to an input pulse of the next precursor of the fabrication sequence. By the use of ALD processes, films may be layered in substantially equal metered sequences that may be substantially the same with respect to chemical kinetics, deposition per cycle, composition, and thickness. ALD sequences generally deposit less than a full layer per cycle. Typically, a deposition or growth rate of about 0.25 to about 2.00 Å per cycle may be realized.

Advantages of ALD depositions over other depositions such as CVD may include superior continuity at an interface avoiding poorly defined nucleating regions typically found in thin chemical vapor deposition (<20 Å) and physical vapor deposition (<50 Å) processes, superior conformality over a variety of substrate topologies due to its layer-by-layer deposition technique, use of low temperature and mildly oxidizing processes, lack of dependence on the reaction chamber, growth thickness that may depend solely on the number of cycles performed, and ability to engineer multilayer laminate films with resolution of one to two monolayers. ALD processes may permit deposition control on the order of single monolayers and the ability to deposit amorphous films.

A cycle of an ALD deposition sequence may include a first precursor material pulse, a purging gas pulse, a second reactant precursor pulse, and the reactant's purging gas pulse, resulting in a deposition thickness that may be a function of the amount of the first precursor that absorbs onto, and saturates, the surface. This ALD cycle may be repeated until the desired thickness is achieved in a single material dielectric layer, or it may be alternated with pulsing a third precursor material, pulsing a purging gas for the third precursor, pulsing a fourth reactant precursor, and pulsing the reactant's purging gas. The resulting thin layers of different dielectric materials, which may be only a few molecular layers thick, may be known as a laminated film, or a “nanolaminate”. A nanolaminate may include a composite film of ultra-thin layers of two or more different materials in a layered stack, where the layers are alternating layers of different materials having a thickness on the order of a nanometer. The nanolayers may not be limited to alternating single layers of each material, but they may include several layers of one material alternating with a single layer of the other material, to obtain a ratio of the two or more materials. Such an arrangement may obtain a dielectric constant that is between the values of the two materials taken singly, or an adjustable band gap that is different from any of the individual layers. The final layer may be made of single layers of the two or more materials deposited individually, whether dielectric, conductive or semiconductive, but it may be considered a single film formed of an alloy between the individual films. This may depend upon the particular materials being used, their physical and chemical properties relative to one another, and any thermal cycling. Miscible materials may result in a single layer or alloy.

In general, the composition of the deposition determines if the final material is conductive (a gate electrode in a MOS transistor), or ferromagnetic (a spintronic device, magnetic memory or a driving electrode in a micromechanical device), or a dielectric (an insulator in a transistor or capacitor). Depending upon the deposition parameters, the zirconium, titanium and hafnium oxides may be amorphous dielectrics having an engineered dielectric constant and used as a gate oxide in a high speed transistor. Under different conditions the result may be crystalline and used in a spintronic device. The zirconium oxide, hafnium oxide and titanium oxide may be formed as a single layer formed in a single reaction, and may have a formula of Ti_{1-X-Y}Zr_{X}Hf_{Y}O₂. Alternatively, they may be formed in separate layers in separate reactions, to obtain a desired semiconductor interface work function. The values of X and Y may be selected to obtain a film having a dielectric constant of greater than 20 for high k gate dielectric devices like transistors that operate faster and with lower power, or they may be selected to obtain a film having an optical band gap value of about 3.2, for spintronic devices. The values of X and Y may be selected to obtain a ferro-magnetic film having a Curie temperature value of greater than 130° C., and used in magnetic memory devices such as MRAMs. The Ti_{1-X-Y}Zr_{X}Hf_{Y}O₂ layer may be produced in various ways, but the uniformity of the layer thickness and the smoothness of the surfaces may be important in spintronic applications, where the tunneling may be sensitive to layer thickness, and in electronic applications, where the leakage current through a gate dielectric may be sensitive to thickness, smoothness and asperities.

In an embodiment, an ALD deposition of zirconium oxide, hafnium oxide and titanium oxide may be formed on a substrate mounted in a reaction chamber in a repetitive sequence using precursor gases individually pulsed into the reaction chamber. An embodiment may include forming a zirconium oxide layer using a metal alkoxy complex precursor gas, such as a tetrakis dialkyl amino zirconium, such as tetrakis dimethlyamine, having a chemical formula of Zr[N(CH₃)₂]4, or tetrakis ethylmethlyamine, having a chemical formula of Zr[N(CH₃) (C₂H₅)], or tetrakis diethlyamine, having a chemical formula of Zr[N(C₂H₅)₂]₄, referred as TDEAZ, or other organometallic compounds. The TDEAZ may be pulsed for about 5 seconds at 350° C., followed by a purge of argon gas for about 5 seconds. Then oxygen may be pulsed for about 5 seconds followed by another argon purge of about 5 seconds, resulting in a zirconium oxide layer of about 0.5 nm per cycle and a surface smoothness of better than 0.5%. Similar results may be found using metal alkoxy complex precursors of hafnium and titanium, and other reactants.

An embodiment may include forming the ZrO₂ layer using ALD with the organometallic compound zirconium tertiary-butoxide as the precursor, having a formula of Zr(OC₄H₉)₄, and referred to as “ZTB”. The deposition may be preformed at 350° C. with water vapor as an oxidizing reactant. The ZTB may be pulsed for 10 seconds, followed by a purge of nitrogen gas for 10 seconds, and water vapor pulsed for 60 seconds, followed by another 10-second inert gas purge, resulting in a 0.05 nm layer of zirconium oxide. A precursor of zirconium tertiary-methoxide having a formula of Zr(O(CH₃)₃)₄ may be used at a temperature of approximately 250° C. with water vapor as a reactant. Other reactants may include ozone, oxygen, nitrous oxide and alcohol.

Another embodiment may include forming a ZrO₂ layer using ALD with zirconium tetrachloride, having a formula of ZrCl₄ as the precursor. The deposition may be performed at 400 to 425° C. with water vapor as the oxidizing reactant. A 0.5 second pulse of ZrCl₄ may be followed by a 0.5 second purge with an inert gas, such as nitrogen, and a 0.5 second pulse of water vapor, resulting in a layer of zirconium oxide having a thickness of about 0.15 nm. Another embodiment includes deposition at 200° C. and may result in a thicker layer of zirconium oxide of 0.33 nm thickness. A similar embodiment may include using a precursor of zirconium tetraiodide having a formula of ZrI₄ at 300° C. with water vapor, resulting in about a 0.45 nm thickness per cycle.

Another embodiment may include forming a ZrO₂ layer using ALD with a precursor comprising zirconium tetraisopropoxide, having a formula of Zr(O-i-Pr)₄, which may be more thermally stable than other potential precursors. The deposition may be preformed at 425° C. with water vapor as the oxidizing reactant.

Another embodiment may include forming a ZrO₂ layer using ALD with a precursor comprising zirconium nitrate, having a formula of Zr(NO₃)₄, which may be known as an anhydrous nitrate, with a reactant of water vapor at a temperature of from 160 to 180° C. The use of an anhydrous nitrate precursor may reduce the amount of carbon trapped in the film while depositing at a relatively low temperature.

Various embodiments for forming hafnium oxide may include hafnium tetra chloride, hafnium tetra iodide, hafnium tetraisopropoxide, hafnium tertiary-butoxide, hafnium tertiary-methoxide, anhydrous hafnium nitrate or tetrakis dialkyl amino hafnium as the ALD precursor, and water vapor as the reactant material as discussed above for the zirconium depositions. Another embodiment may include hafnium nitride, Hf(NO₃)₄ as the precursor at 300° C. with pulse times of 0.6 seconds, with a reactant of water vapor, resulting in about a 0.36 nm film per cycle. Hafnium oxide films may be formed at temperatures as low as 150° C. using a tetrakismethylethylamino hafnium precursor and may result in a slow controlled film growth of 0.09 nm per cycle.

Various embodiments for forming titanium oxide may include titanium tetra chloride, titanium tetra iodide, titanium tetraisopropoxide, titanium tertiary-butoxide, titanium tertiary-methoxide, titanium nitrate or tetrakis dialkyl amino titanium as the ALD precursor, and water vapor as the reactant material, as discussed above for the zirconium and hafnium depositions. Titanium, zirconium and hafnium are chemically similar elements that occupy column IVA of the periodic table of elements.

Other solid or liquid precursors may be used in an appropriately designed reaction chamber (known as a reactor) for any of the above materials. The use of such precursors in an ALD reaction chamber may result in lower deposition temperatures in the range of 180° C. to 400° C., and the ability to use mildly oxidizing reactant materials such as water (H₂O), hydrogen peroxide (H₂O₂), various alcohol vapors, nitrous oxide (N₂O) or other oxides of nitrogen, ozone (O₃) or oxygen. Purge gases may include hydrogen, nitrogen, helium, argon, krypton or neon. It should be noted that the use of the term reactant may mean a precursor material that is added to the ALD reactor to react with the previously introduced precursor material, to form a layer of the product material. It should be noted that there may be no difference between a precursor material and a reactant material other than the order in which they enter the reactor. The terms are used to facilitate understanding the principles of the disclosed arrangements, and they are not intended to be used in a limiting sense.

It should be noted that the above-mentioned embodiments are not intended to be limited to a single deposition cycle of each of the materials, but rather they may have multiple layers of one material deposited prior to the other materials being deposited, in order to obtain the desired final composition.

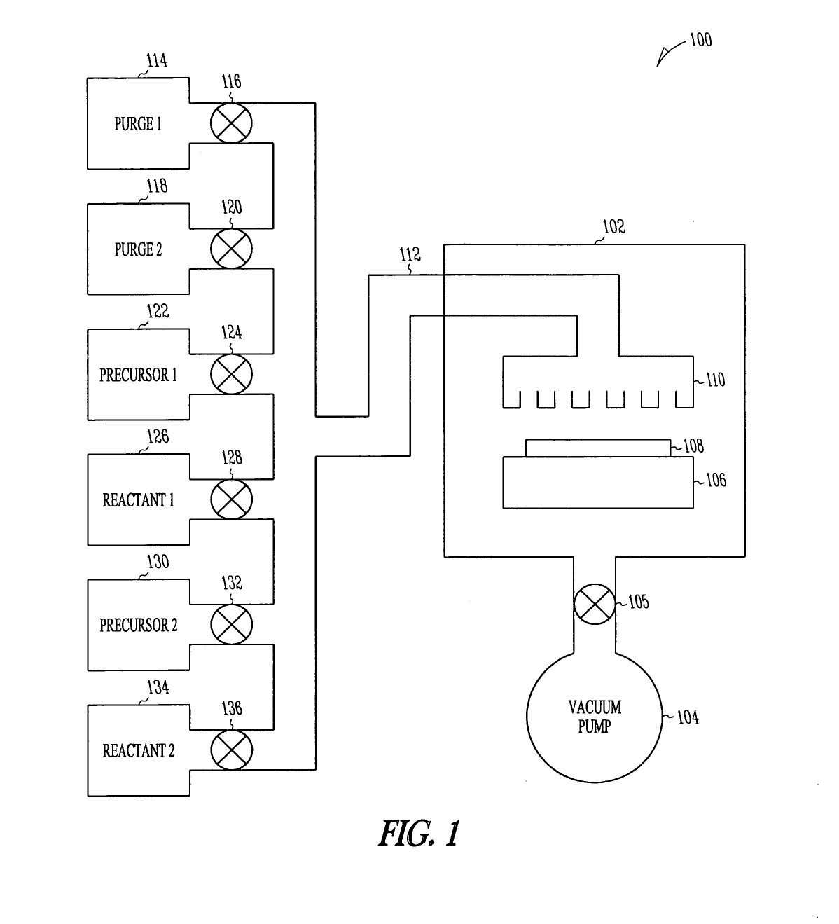

FIG. 1 depicts an atomic layer deposition system 100 suitable for forming a layer of zirconium oxide, hafnium oxide, and titanium oxide. In an embodiment the layer may contain titanium oxide (either in a crystalline form such as rutile, or in an amorphous form) having an approximate formula of ZrO₂, zirconium oxide having an approximate formula of ZrO₂, and hafnium oxide having an approximate formula of HfO₂, according to various embodiments. The elements depicted permit discussion of the described embodiments such that those skilled in the art may practice these embodiments without undue experimentation. In FIG. 1, a substrate 108 on a heating element/wafer holder 106 may be located inside a reaction chamber 102 of ALD system 100. The heating element 106 may be thermally coupled to substrate 108 to control the substrate temperature. A gas-distribution fixture 110 may introduce precursor, reactant and purge gases to the region of the surface of substrate 108 in a substantially uniform fashion. The gases introduced by the gas distribution fixture 110, sometimes referred to as a showerhead, may react with the substrate 108, and excess precursor gases and reaction products may be removed from the chamber 102 by a vacuum pump 104 through a control valve 105. The system 100 may operate at any desired deposition pressure by controlling the volume of gas entering the chamber 102 as compared to the volume of gaseous reaction product and excess gases removed from the chamber 102 via control of the pumping rate of vacuum pump 104 and the valve 105. ALD systems may operate at normal atmospheric pressures, at above normal atmospheric pressure or may operate under vacuum conditions. In some embodiments, ALD layers may be formed at a reduced pressure of 10⁻⁵ Torr pressure with an oxygen gas plasma with a 100 Watt radio-frequency (RF) generator (not shown) providing the oxidation reactant. Such an arrangement may result in a less contaminated final film, especially with respect to possible carbon contamination from excess carbon in some of the precursors discussed above, such as tetrakis diethlyamine, Zr[N(C₂H₅)₂]₄, or other organometallic compounds.

Each precursor, reactant or purge material may originate from individual material sources 114, 118, 122, 126, 130, and 134, with a flow rate and time controlled by mass-flow controllers 116, 120, 124, 128, 132 and 136, respectively. In the present illustrative embodiment the sources 118, 122 and 126 provide the three necessary precursor materials, either by storing the precursor as a gas or by evaporating a solid or liquid material to form the selected precursor flow by evaporation, sublimation or entrainment in a gas stream.

Also included is a single purging gas source 114, although the invention is not so limited, and numerous different purge gases, such as nitrogen, argon, helium, neon, hydrogen and krypton may be provided, and used either individually, in combination, simultaneously or sequentially. The purge gas source 114 is coupled to mass-flow controller 116. Two reactant material sources, 130 and 134, are connected through mass-flow controllers 132 and 136. The precursor, reactant and purge gas sources may be coupled by their associated mass-flow controllers to a common gas line or conduit 112, which may be coupled to the gas-distribution fixture 110 inside the reaction chamber 102. Gas conduit 112 may also be coupled to another vacuum pump, or exhaust pump, not shown, to remove excess precursor gases, purging gases, and by-product gases at the end of a purge cycle from the gas conduit 112.

The vacuum pump, or exhaust pump, 104 may be coupled to chamber 102 by control valve 105, which may comprise a mass-flow valve, to remove excess precursor gases, purging gases, and by-product gases from reaction chamber 102 at the end of a purging sequence. For convenience, control displays, mounting apparatus, temperature-sensing devices, substrate-maneuvering apparatus, and electrical connections, known to those skilled in the art are not shown in FIG. 1. Though the ALD system 100 shown in FIG. 1 is well suited for practicing the present illustrative embodiments, other commercially available ALD systems may also be used.

The use, construction and fundamental operation of reaction chambers for deposition of films are understood by those of ordinary skill in the art of semiconductor fabrication. The embodiments, as disclosed herein, as well as others, may be practiced on a variety of such reaction chambers without undue experimentation. One of ordinary skill in the art will comprehend the detection, measurement, and control techniques used in the art of semiconductor fabrication that are not specifically disclosed herein, and those skilled in the art will also appreciate that the individual elements such as pressure control, temperature control, and gas flow within ALD system 100 can be under computer control, upon reading the disclosure. The elements of ALD system 100 may be controlled by a computer.

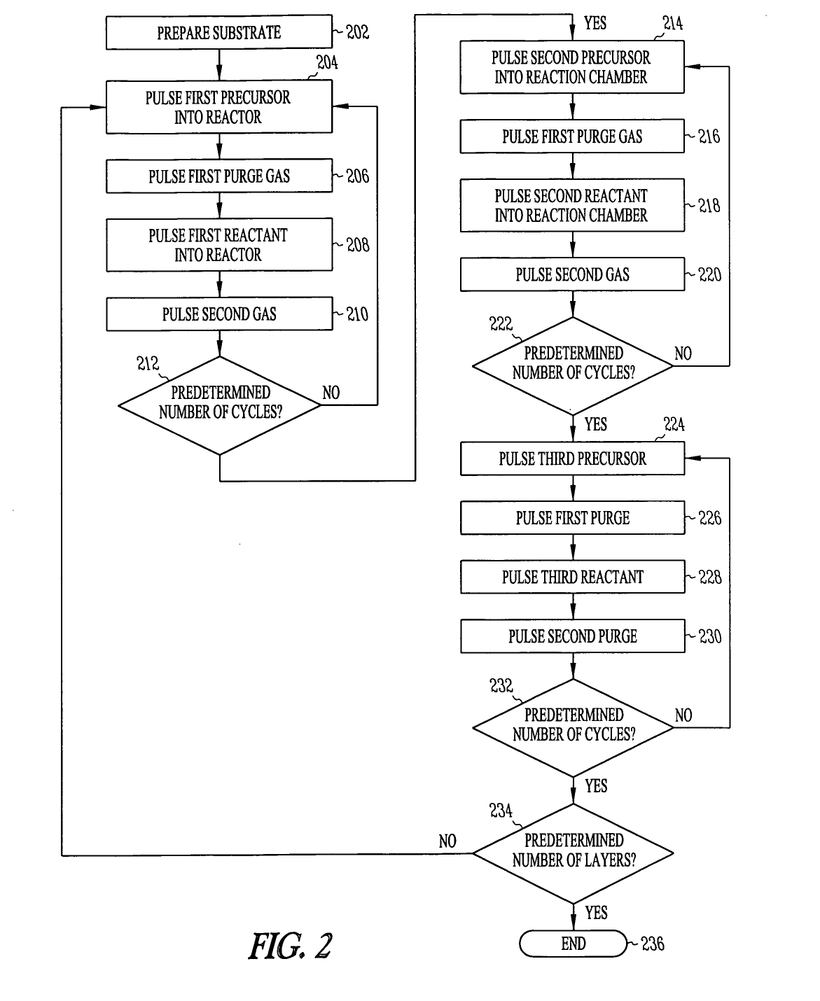

FIG. 2 illustrates a flow diagram of a method to form a layer by atomic layer deposition according to various embodiments. Note that the resulting laminate layer may act as a single layer having a general formula of the form Ti_{1-X-Y}Zr_{X}Hf_{Y}O₂, where the individual layers forming the final layer may be stoichiometric pure films, such as TiO₂, or may be close to the stoichiometric ratio, or may be non-stoichiometric, as the final film may also have any ratio of component parts. The individual layers may be crystalline or amorphous, depending upon the deposition parameters and any subsequent heat processing, such as may be found in typical MOS device processing. The individual layers may be dielectric, conductive or semiconductive in nature.

At block 202, a substrate may be prepared to react immediately with, and chemisorb the first precursor gas. This preparation may serve to remove contaminants such as thin organic films, dirt, and native oxide from the surface of the substrate, and it may include a hydrofluoric acid rinse, a hydrogen termination process to provide a activated surface, or a sputter etch.

At block 204 a first precursor material may enter the reaction chamber for a predetermined length of time, in an embodiment Hf(NO₃)₄, for example from 0.5-2.0 seconds, but other hafnium-containing gases, liquids and sublimating solids may also be used as discussed previously. One advantage of the use of Hf(NO₃)₄ is that the final film may be free of carbon, hydrogen or halogen contamination. The first precursor material may be chemically adsorbed onto the surface of the substrate, the amount depending at least in part upon the temperature of the substrate, which in one embodiment is 300° C., and at least in part on the presence of sufficient flow of precursor material. The initial film does not have to be hafnium oxide, and it may equally well be titanium or zirconium.

At block 206 a first purge gas may enter the reaction chamber for a predetermined length of time sufficient to remove substantially all of the non-chemisorbed first precursor material. Typical times may be 0.4-2.0 seconds, with the purge gas comprising nitrogen, argon, neon, hydrogen and combinations thereof.

At block 208 a first reactant gas may enter the chamber for a predetermined length of time sufficient to provide enough of the reactant material to chemically combine with substantially all of the chemisorbed first precursor material on the surface of the substrate. In an embodiment, the reactant material for the first precursor comprises water vapor (i.e., H₂O) for a pulse length of about 0.60 seconds. Suitable reactant materials may include mildly oxidizing materials, including, but not limited to, water vapor, hydrogen peroxide, nitrogen oxides such as nitrous oxide, ozone, oxygen gas, plasmas of the same, and combinations thereof.

At block 210 a second purge gas, which may be the same or different from the first purge gas, may enter the chamber for a predetermined length of time, sufficient to remove substantially all non-reacted materials and reaction byproducts from the chamber. At this point, it may be said that a single ALD cycle has been completed.

At block 212 a decision may be made as to whether the thickness of the first material in the illustrative laminate layer has reached the desired thickness, or whether another deposition cycle should be performed. In an embodiment, the thickness of the HfO₂ layer obtained from a single ALD cycle may be 0.33 nm. If another deposition cycle is used to reach the desired thickness, then the operation may return to block 204 and repeat the deposition process until the desired first dielectric layer is completed. If the thickness of the first dielectric material is at or above the desired thickness, the process may move to the deposition of the second material at block 214.

At block 214 a second precursor material for the second material may enter the reaction chamber for a predetermined length of time, typically 0.5-2.0 seconds. In an embodiment the precursor material may include tetrakisdiethylamino zirconium, TDEAZ, but other zirconium-containing materials, in gas, liquid or sublimating solid form may also be used. The second precursor material may be chemically adsorbed onto the surface of the substrate, in this case being the top surface of the first material. The absorption level may depend upon the temperature of the substrate, in one embodiment 300° C., and the presence of sufficient flow of the precursor material. In addition, the pulsing of the precursor may use a pulsing period that provides uniform coverage of an absorbed monolayer on the substrate surface, or it may use a pulsing period that provides partial formation of a monolayer on the substrate surface.

At block 216 the first purge gas is shown as entering the chamber, but the invention is not so limited. The purge gas used in the second dielectric material deposition may be the same or different from either of the two previously noted purge gases, and FIG. 1 may be shown as having more than the one purge gas source shown. The purge cycle continues for a predetermined length of time sufficient to remove substantially all the non-chemisorbed second precursor.

At block 218 a second reactant gas, which may the same or different from the first reactant gas, may enter the chamber for a predetermined length of time, sufficient to provide enough of the reactant to chemically combine with the chemisorbed second precursor material on the surface of the substrate. In an embodiment the reactant used with the TDEAZ precursor comprises water vapor with a pulse time of about 2.0 seconds, resulting in a 0.10 nm layer of ZrO₂.

At block 220 another purge gas enters the chamber, which may be the same or different from any of the three previously discussed purge gases, for a predetermined length of time, sufficient to remove non-reacted materials and any reaction byproducts from the chamber.

At block 222 a decision may be made as to whether the thickness of the second dielectric material in the laminate dielectric structure has reached a predetermined thickness, or whether another deposition cycle is desired. If another deposition cycle is needed, then the operation may return to 214, until the second layer is completed. The thicknesses of the first and second materials in the laminate may not be the same, and there may be more deposition cycles for one material than for the other.

If the second layer has reached the desired thickness, the process may move to block 224, where a third precursor enters the reactor. In an embodiment the third precursor is a titanium tetrachloride pulse lasting about 0.20 seconds at approximately 300° C. Again, the third precursor chemisorbs onto the surface, at this point the second film, ZrO₂. The illustrative embodiment has a particular order of precursors; however the invention is not so limited, and any of the three precursors may be used in any order, in accordance with the final film characteristics.

At block 226 another purge occurs to remove non-chemisorbed portions of the third precursor, and at block 228 the third reactant is pulsed into the reactor. The third reactant may be the same as the previous reactants, or the third reactant may be a different material, and in an embodiment it is water vapor pulsed for about 0.20 seconds. At block 230 another purge occurs.

At block 232 a decision is made as to whether or not the third material has reached the predetermined thickness. If another deposition cycle is needed, then the operation may return to block 224, until the desired second dielectric layer is completed. The desired thicknesses of the first, second and third materials in the laminate structure may not be the same thickness, and there may be more deposition cycles for one material as compared to the others. If the third material has reached the desired thickness, the operation may move to block 234, where it is determined if the first, second and third materials have reached the desired number of layers for the finished film. If more than a single layer of each material is desired, then the process may move back to another deposition of the first material at block 204. After the number of interleaved layers of the first, second and third materials has reached the desired value, the deposition may end at block 236. Although the present embodiment discusses and illustrates the layers as distinct from each other, the individual layers may be very thin and may act effectively as a single alloy layer, or subsequent heat cycles may anneal or alloy the individual layers into a single material layer. The present embodiment illustrates the hafnium oxide layer as being deposited first, but the invention is not so limited. The embodiment may not be limited to the described three material layers. Altering the deposition temperature and relative proportions of the precursors may result in a crystalline semiconductor layer of titanium zirconium hafnium oxide having ferromagnetic properties, rather than a dielectric.

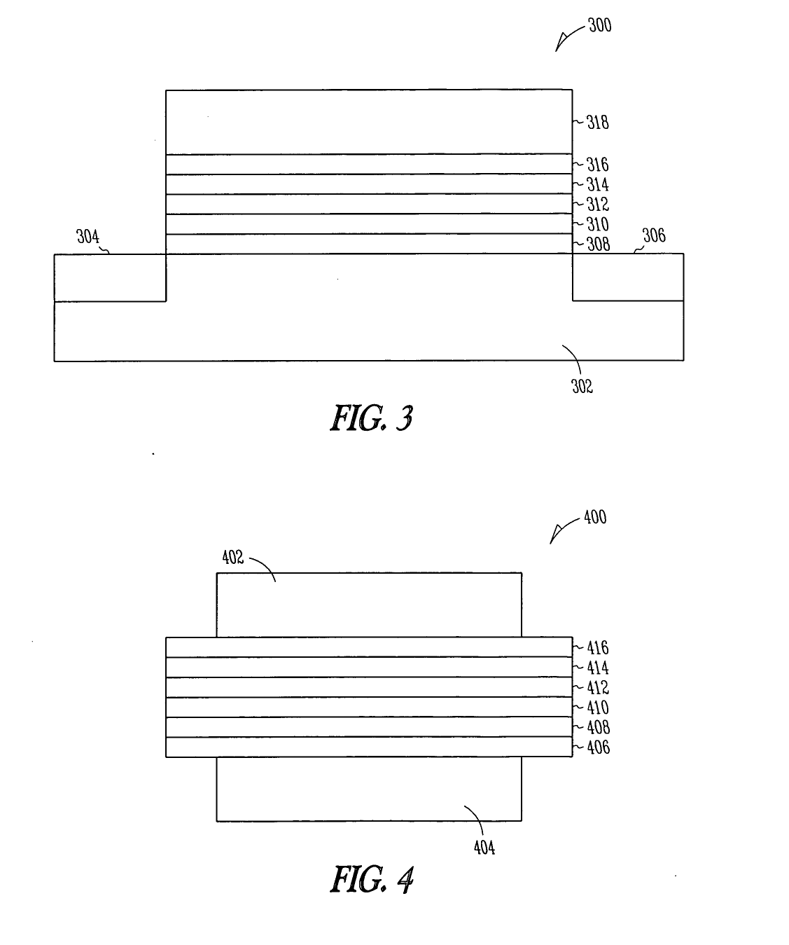

FIG. 3 illustrates a transistor 300 containing a structure deposited according to various embodiments. The first layer may contain a titanium oxide alternating with a hafnium oxide layer and with a zirconium oxide layer forming a deposited zirconium oxide/hafnium oxide/titanium oxide gate insulator layer. A substrate 302 may be prepared for deposition, typically a silicon or silicon-containing material; however, other semiconductor materials such as germanium, gallium arsenide, and silicon-on-sapphire may also be used. This preparation process may include cleaning substrate 302 and forming various layers and regions of the substrate, such as drain diffusion 304 and source diffusion 306 of an illustrative metal oxide semiconductor (MOS) transistor 300, prior to forming a gate dielectric. The substrate 302 is typically cleaned to provide an initial substrate depleted of its native oxide, since the presence of a thin layer of SiO₂ may result in decreased capacitive coupling. The substrate may also be cleaned to provide a hydrogen-terminated surface, which may be known as an activated surface, to improve the rate of chemisorption. In an embodiment, a silicon substrate may undergo a final hydrofluoric (HF) acid rinse prior to ALD processing to provide the silicon substrate with a hydrogen-terminated surface having no native silicon oxide layer. Cleaning preceding atomic layer deposition may aid in reducing the presence of silicon oxide at an interface between the silicon-based substrate and the dielectric formed using the atomic layer deposition process. The sequencing of the formation of the regions of the transistor being processed may follow typical sequencing that is generally performed in the fabrication of a MOS transistor, as is well known to those of ordinary skill in the art.

The dielectric covering the area on the substrate 302 between the source and drain diffused regions 304 and 306 is deposited by ALD in this illustrative embodiment, and it comprises titanium oxide layers 308 and 314, having interleaved zirconium oxide layers, 310 and 316, and a single hafnium oxide layer 312 in the middle. The single shown layer 312 of hafnium oxide is not intended to be limiting, and the number of different layers may depend upon the desired final composition, which may affect the oxygen barrier properties and dielectric constant.

This alloy dielectric structure may be referred to as the gate oxide. In this embodiment the titanium oxide layer 308 is shown as being the first layer and in direct contact with the substrate 302; however, the invention is not so limited. There may be a diffusion barrier layer inserted between the first dielectric layer 308 and the substrate 302 to prevent metal contamination from affecting the electrical properties of the device. The embodiment may also include having the first dielectric layer be zirconium oxide, since this may affect the level of surface states and the work function of the dielectric layer. The embodiment also shows the different dielectric layers having the same thickness; however the desired properties of the film, such as dielectric constant, may be best achieved by adjusting the ratio of the thickness of the dielectric materials to different values. Even though the illustrative embodiment shows the various oxide layers as being distinct from each other, the gate oxide (all the layers 308 to 316) in total may appear to be a single alloyed dielectric layer having a formula of Ti_{1-X-Y}Zr_{X}Hf_{Y}O₂. The transistor 300 has a conductive material forming a single gate electrode 318 in this embodiment, but the dielectric may also be used in a floating gate device such as flash memory.

In an embodiment, gate dielectric (comprising layers 308, 310, 312, 314, 316) may form a tunnel gate insulator and a floating gate dielectric in a flash memory device. Use of dielectric layers containing laminated ALD dielectric layers for a gate dielectric and/or floating gate dielectric in which the dielectric layer contacts a conductive layer is not limited to silicon-based substrates, but it may be used with other semiconductor substrates.

FIG. 4 illustrates a capacitor 400 containing a dielectric structure deposited according to various disclosed embodiments. Embodiments of methods for forming ALD deposited structures contacting a conductive layer may also be applied to forming spintronic devices such as tunnel devices and non-volatile memory devices, as well as capacitors in various integrated circuits, memory devices, and electronic systems. In an embodiment for forming a capacitor 400, a method may include forming a first conductive layer 402, a second conductive layer 404, and a dielectric having interleaved layers 406, 408, 410, 412, 414 and 416 of at least three different dielectric materials, formed between the two conductive layers. The conductive layers 402, 404 may comprise metals, doped polysilicon, silicided metals, polycides, or conductive organic compounds, without affecting the teaching of this embodiment. The sequencing of the layers may depend upon the application, or it may be less important in the case of an alloyed single layer, such as the described embodiment of an effectively single dielectric structure having layers 406 and 412 formed of HfO₂, layers 408 and 414 formed of ZrO₂, and layers 410 and 416 formed of titanium oxide, but the invention does not require that there be an even number of layers, or that the layers be deposited in any particular order, or that the order be repeated. The effective dielectric constant associated with a laminate structure may be attributable to N capacitors in series, where each capacitor has a thickness defined by the thickness of the corresponding layer. By selecting each thickness and the composition of each layer, a laminated structure can be engineered to have a predetermined dielectric constant. Structures such as laminate structure shown in FIGS. 3 and 4 may be used in non-volatile flash memory devices as well as other integrated circuits. Transistors (e.g., a bipolar transistor, a MOS transistor), capacitors, and other devices having dielectric films may be implemented into memory devices, logic devices, mixed signal devices, displays, set top boxes and electronic systems including information-handling devices. Embodiments of these information-handling devices may include wireless systems, telecommunication systems, computers, portions of vehicles and integrated circuits.

FIG. 5 is a simplified diagram of a controller coupled to an electronic device according to various embodiments. An embodiment includes an illustrative electronic system 500 having one or more devices including a dielectric structure containing an atomic layer deposited oxide layer formed according to various embodiments of the present invention. The electronic system 500 may include a controller 502, a bus 504, and an electronic device 506, where bus 504 provides electrical conductivity between controller 502 and electronic device 506. In various embodiments, the controller 502 and/or electronic device 506 may include a dielectric structure containing an ALD deposited oxide layer as previously discussed herein. System 500 may include information-handling, wireless, telecommunication, fiber optic, automotive, electro-optic, and computer systems.

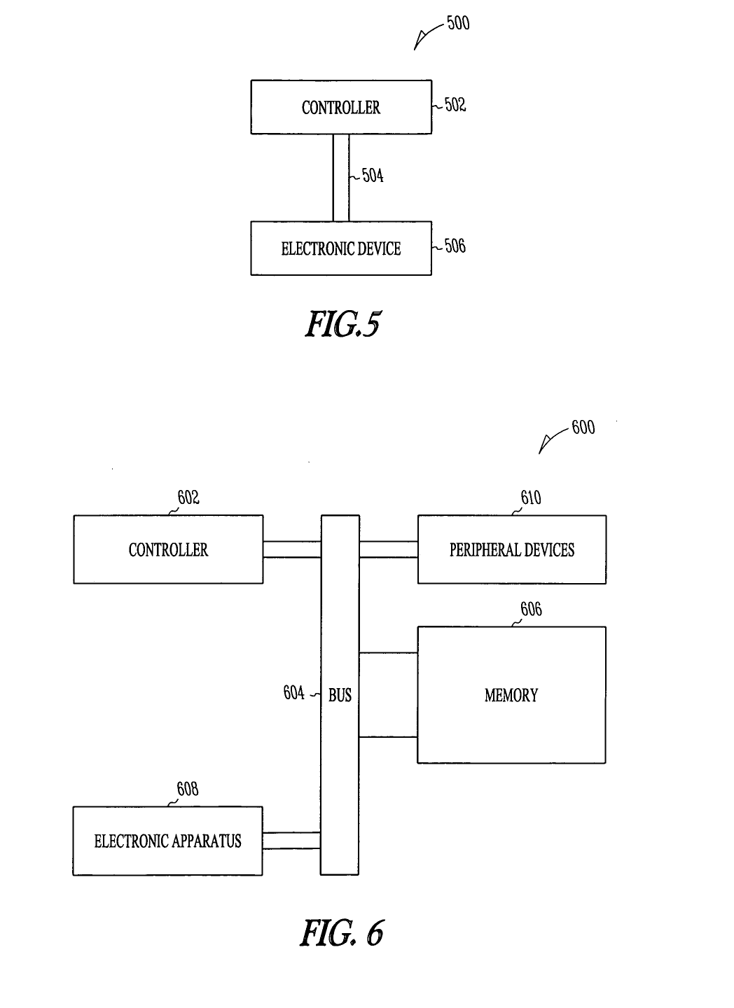

FIG. 6 illustrates a diagram of an electronic system 600 having at least some devices with a dielectric film formed according to various disclosed embodiments. An embodiment of an electronic system 600 may include a controller 602 and a memory 606. Controller 602 and/or memory 606 may include a dielectric layer having an ALD dielectric layer. The system 600 also may include an electronic apparatus 608, and a bus 604, where the bus 604 may provide electrical conductivity and data transmission between controller 602 and electronic apparatus 608, and between controller 602 and memory 606. The bus 604 may include an address, a data bus, and a control bus, each independently configured. The bus 604 may use common conductive lines for providing address, data, and/or control, the use of which may be regulated by the controller 602. In some embodiments, the electronic apparatus 608 may include additional memory devices configured similarly to the memory 606. Some embodiments may include one or more additional peripheral devices 610 coupled to the bus 604. In an embodiment, the controller 602 comprises a processor. Any of the controller 602, the memory 606, the bus 604, the electronic apparatus 608, and peripheral devices 610 may include a dielectric structure having an ALD deposited oxide layer in accordance with the disclosed embodiments.

System 600 may include, but is not limited to, information-handling devices, telecommunication systems, personal communication systems, personal computing systems such as laptop computers and personal digital assistants (PDAs) and computers. Peripheral devices 610 may include displays, additional storage memory, or other control devices that may operate in conjunction with controller 602 and/or memory 606. It will be understood that embodiments are equally applicable to any size and type of memory circuit and are not intended to be limited to a particular type of memory device. Memory types include a DRAM (Dynamic Random Access Memory), SRAM (Static Random Access Memory) or Flash memories. Additionally, the DRAM may comprise a synchronous DRAM commonly referred to as SGRAM (Synchronous Graphics Random Access Memory), SDRAM (Synchronous Dynamic Random Access Memory), SDRAM II, and DDR SDRAM (Double Data Rate SDRAM), as well as Synchlink or Rambus DRAMs and other emerging DRAM technologies.

The detailed description refers to the accompanying drawings that show, by way of illustration, specific aspects and embodiments in which the present disclosed embodiments may be practiced. These embodiments are described in sufficient detail to enable those skilled in the art to practice aspects of the present invention. Other embodiments may be utilized, and structural, logical, and electrical changes may be made without departing from the scope of the disclosed embodiments. The various embodiments are not necessarily mutually exclusive, as some embodiments can be combined with one or more other embodiments to form new embodiments.

The terms “wafer” and “substrate” as used in this description may include any structure having an exposed surface with which to form an integrated circuit (IC) structure. The term “substrate” is understood to include semiconductor wafers. The term “substrate” is also used to refer to semiconductor structures during processing, and it may include other layers that have been fabricated thereupon. Both “wafer” and “substrate” may include doped and undoped semiconductors, epitaxial semiconductor layers supported by a base semiconductor or insulator, as well as other semiconductor structures well known to one skilled in the art. The term “conductor” is understood to generally include n-type and p-type semiconductors, and the term “insulator” or “dielectric” is defined to include any material that is less electrically conductive than the materials referred to as conductors or as semiconductors.

The term “horizontal” as used in this application is defined as a plane parallel to the conventional plane or surface of a wafer or substrate, regardless of the orientation of the wafer or substrate. The term “vertical” refers to a direction perpendicular to the horizontal as defined above. Prepositions, such as “on”, “side” (as in “sidewall”), “higher”, “lower”, “over” and “under” are defined with respect to the conventional plane or surface being on the top surface of the wafer or substrate, regardless of the orientation of the wafer or substrate. This detailed description is, therefore, not to be taken in a limiting sense, and the scope of the present invention is defined only by the appended claims, along with the full scope of equivalents to which such claims are entitled.

It should be noted that the methods described herein do not have to be executed in the order described, or in any particular order. Moreover, various activities described with respect to the methods identified herein can be executed in serial or parallel fashion. It will be understood that although an “End” block is shown in FIG. 2, the method may be performed continuously.

An embodiment of a method for forming an electronic or a spintronic device may include forming a metal oxide layer by an atomic layer deposition (ALD) to form a laminated or layered structure having layers of zirconium oxide (ZrO₂), hafnium oxide (HfO₂) and titanium oxide (TiO₂). The structure may act as a single dielectric layer or a single magnetic layer, and it may be formed by depositing the various metal oxides by atomic layer deposition onto a substrate surface using precursor chemicals containing zirconium, followed by a purge and deposition of an oxidizing material such as ozone, hydrogen peroxide or water vapor to form a thin (often a single molecular layer) film of ZrO₂. Formation may continue with ALD depositing hafnium oxide using precursor chemicals containing hafnium, followed by a purge and deposition of an oxidizing material such as ozone or water vapor to form a thin film of HfO₂, followed by ALD deposition of a titanium oxide layer using precursor chemicals containing titanium, followed by a purge and deposition of an oxidizing material such as ozone or water vapor to form a thin film of TiO₂. The above three film formations may be repeated as often as necessary to form a thin laminate dielectric structure of the desired thickness. The order of forming the three films is not limited to the discussed order, but it may be varied to obtain any desired combination, and the final film may be high temperature processed to anneal, or alloy, the three layers to act as a single uniform layer rather than as three separate films. A dielectric structure formed of zirconium oxide, hafnium oxide and titanium oxide may be beneficially used in electronic devices because the high dielectric constant (high k) of the film may provide the functionality of a thinner silicon dioxide film with fewer reliability issues. A ferromagnetic layer formed in a similar fashion, but under different conditions, which may include forming the TiO₂ under conditions appropriate for crystalline formation, may provide a useful layer for spintronic devices.

Another embodiment may include forming the dielectric or ferromagnetic structure as a single film having a formula of Ti_{1-X-Y}Zr_{X}Hf_{Y}O₂. The film may be formed by atomic layer deposition by using a mixed precursor. An example of a process to form a single film may include the mixing of selected volumes of HfCl₄, TiCl₄, and ZrCl₄, the introduction of the mixture into a reactor at 250° C. for a time sufficient to allow the mixed precursors to chemisorb onto the surface, for example 5 seconds. An argon purge flow may follow the precursor flow for about 5 seconds, followed by a reactant flow of water vapor for about 5 seconds. The ALD cycle may be completed by another argon purge flow for about 5 seconds, resulting in a thin substantially uniform layer having an approximate formula of Ti_{1-X-Y}Zr_{X}Hf_{Y}O₂. The values of X and Y may depend upon the chemisorption of the individual precursors, the volume of the individual precursors and the temperature. The precursors used may not have similar chemical structures as used in the present illustrative example, and any combination of different chemical types may be used.

The addition of zirconium oxide to produce a controlled compositional spread of hafnium and titanium oxides may provide a more stable silicon insulator interface, may have a larger bandgap and thus better insulation properties, and may provide the ability to adjust the dielectric constant k, and the film microstructure to the particular electronic device application. The titanium oxide may be grown in a crystalline form, either in a substantially pure form, or with a doping of hafnium and/or zirconium. The crystalline form of the Ti_{1-X-Y}Zr_{X}Hf_{Y}O₂ material may be used as a ferromagnetic material in spintronic devices.

Embodiments may include structures for capacitors, transistors, memory devices, and electronic systems with dielectric structures containing an atomic layer deposited zirconium oxide, hafnium oxide and titanium oxide layers, having various individual layer thickness, layer order and number of layers of each individual material, and methods for forming such structures. Other embodiments may include the use of the crystalline form and include optoelectronic devices, spintronic devices and tunnel diodes.

An embodiment of a method may include forming a dielectric structure including at least zirconium oxide, hafnium oxide and titanium oxide on a surface of a substrate, and forming a conductive layer on the dielectric layer. The conductive layer may be a gate electrode in a MOS transistor, a ferromagnetic layer in a spintronic device, or a driving electrode in a micromechanical device. The zirconium oxide may have a formula ZrO₂, the hafnium oxide may have a formula of HfO₂, and the titanium oxide may have a formula of TiO₂. The zirconium, titanium and hafnium oxides may be amorphous, for example in a gate oxide, or may be crystalline, as in a spintronic layer. The zirconium oxide, hafnium oxide and titanium oxide may be formed as a single layer formed in a single reaction, as well as in individual layers, and may have a formula of Ti_{1-X-Y}Zr_{X}Hf_{Y}O₂. The values of X and Y may be selected to obtain a film having a dielectric constant of greater than 20 for high k gate dielectric devices, or they may be selected to obtain a film having an optical band gap value of about 3.2, for spintronic devices. The values of X and Y may be selected to obtain a ferro-magnetic film having a Curie temperature value of greater than 130° C., if the single layer has a crystal structure that may be either anatase titanium oxide, or rutile titanium oxide, both of which may be used as spintronic device layers. The film, whether formed as a single layer, or as a series of layers that are annealed to form a single layer, may have X in a range of from 0.05 to 0.35, and Y in a range of from 0.05 to 0.25, and still maintain its crystalline nature and spintronic effect. A particular set of values, where X may be 0.10, and Y may be 0.18, may result in a spintronic layer having a high optical bandgap of about 3.26, which may be useful in spintronic and optoelectronic devices. The Ti_{1-X-Y}Zr_{X}Hf_{Y}O₂ layer may be produced in various ways, but the uniformity of the layer thickness and the smoothness of the surfaces may be important in both spintronic applications, where the tunneling may be sensitive to layer thickness, and in electronic applications, where the leakage current through a gate dielectric may be sensitive to thickness and asperities. A deposition method that may address these possible issues may include forming the zirconium oxide, hafnium oxide and titanium oxide by atomic layer deposition.

Hafnium oxide/zirconium/titanium oxide layers formed by ALD may be processed at relatively low temperatures, such as 300° C., and may be amorphous and possess smooth surfaces. Such oxide films may provide enhanced electrical properties as compared to those formed by physical deposition methods, such as sputtering, or typical chemical layer depositions, due to their smoother surface and reduced damage, which may result in reduced leakage current. The use of such oxide films or layers may increase the dielectric constant and electrical insulation properties of the final film. Such dielectric layers may have adjustable dielectric constants that are higher than the commonly used silicon dioxide and silicon nitride based dielectrics, and they may provide a significantly thicker physical thickness than a silicon oxide layer having the same equivalent oxide thickness, where the increased thickness may reduce leakage current and reduce oxide shorts due to pinholes and other reduced thickness areas. These properties may allow application as dielectric layers in numerous electronic devices and systems.

Capacitors, transistors, higher level ICs or devices including memory devices, and electronic systems may be constructed utilizing the described ALD process for forming a dielectric film having a thin equivalent oxide thickness, t_{eq}. Gate dielectric layers or films containing atomic layer deposited metal oxides have a dielectric constant (k) substantially higher than that of silicon dioxide, such that these dielectric films are capable of a t_{eq} thinner than SiO₂ gate dielectrics of the same physical thickness. Alternatively, the high dielectric constant relative to silicon dioxide may enable the use of a greater physical thickness of these high k dielectric materials for the same t_{eq} of SiO₂. These described dielectric structures may be portions of various other devices, such as cameras, phones, wireless communication devices, displays, chip sets, set top boxes, games or vehicles. Spintronic devices and optoelectronic devices may use the described crystalline films in diluted magnetic semiconductor (DMS) devices and transparent ferromagnetic devices, such as magneto-optical devices with Currie temperatures well above room temperature, as high as 400° K., or 130° C. Spintronic devices may include tunnel diodes and non-volatile memory devices. For the described films to be useful in spintronic devices, the film may be a crystalline wide bandgap semiconductor oxide, and it may have the specific crystal structure known as rutile, or the crystal structure known as anatase. It will be understood by one of ordinary skill in the art that specific amounts described herein, such as times, pressures, dimensions, quantities, and the like are approximate and may be suitably adjusted.

Although specific embodiments have been illustrated and described herein, it will be appreciated by those of ordinary skill in the art that any arrangement that is calculated to achieve the same purpose may be substituted for the specific embodiments shown. This application is intended to cover any adaptations or variations of embodiments of the present invention. It is to be understood that the above description is intended to be illustrative, and not restrictive, and that the phraseology or terminology employed herein is for the purpose of description and not of limitation. Combinations of the above embodiments and other embodiments will be apparent to those of skill in the art upon studying the above description. The scope of the present disclosed embodiments includes any other applications in which embodiments of the above structures and fabrication methods are used. The scope of the embodiments should be determined with reference to the appended claims, along with the full scope of equivalents to which such claims are entitled.

What is claimed is:

1. A method comprising:
forming a dielectric structure including at least zirconium oxide, hafnium oxide and titanium oxide on a surface of a substrate; and
forming a conductive layer on the dielectric layer.

2. The method of claim 1, wherein forming the zirconium oxide includes forming an oxide layer having a formula of ZrO₂, wherein forming the hafnium oxide includes forming an oxide layer having a formula of HfO₂, and wherein forming the titanium oxide includes forming an oxide layer having a formula of TiO₂.

3. The method of claim 2, further comprising forming the zirconium oxide and hafnium oxide in amorphous form.

4. The method of claim 1, further comprising forming the zirconium oxide, hafnium oxide and titanium oxide as a single layer in a single reaction.

5. The method of claim 1, further comprising forming the zirconium oxide, hafnium oxide and titanium oxide as a single layer having a formula of Ti_{1-X-Y}Zr_{X}Hf_{Y}O₂.

6. The method of claim 5, further comprising selecting the values of X and Y to obtain a film having a dielectric constant greater than 20.

7. The method of claim 5, further comprising selecting the values of X and Y to obtain a film having an optical band gap value of about 3.2 eV.

8. The method of claim 5, further comprising selecting the values of X and Y to obtain a ferro-magnetic film having a Curie temperature value greater than 130° C.

9. The method of claim 5, further comprising forming the single layer to exhibit a crystal structure.

10. The method of claim 9, further comprising forming the crystal structure to be one of anatase and rutile.

11. The method of claim 10, wherein X is selected to have a range of from 0.05 to 0.35, and wherein Y has a range of from 0.05 to 0.25.

12. The method of claim 10, wherein X is selected to be 0.10 and Y is selected to be 0.18.

13. The method of claim 1, wherein the method includes forming the zirconium oxide, hafnium oxide and titanium oxide by atomic layer deposition.

14. The method of claim 1, wherein the zirconium oxide layer is formed by including a zirconium precursor selected from zirconium anhydrous nitrate, zirconium tetrachloride, zirconium tetraiodide, zirconium tetrakisdiaklyamine, zirconium tetraisopropoxide, zirconium tertiary-methoxide and zirconium tertiary-butoxide;
wherein the hafnium oxide layer is formed by including a hafnium precursor selected from hafnium anhydrous nitrate, hafnium tetrachloride, hafnium tetraiodide, hafnium tetrakisdiaklyamine, hafnium tetraisopropoxide, hafnium tertiary-methoxide and hafnium tertiary-butoxide;
wherein the titanium oxide layer is formed by including a titanium precursor selected from titanium anhydrous nitrate, titanium tetrachloride, titanium tetraiodide, titanium tetrakisdiaklyamine, titanium tetraisopropoxide, titanium tertiary-methoxide and titanium tertiary-butoxide; and
wherein the forming includes at least one of water vapor, oxygen, ozone, hydrogen peroxide, nitrous oxide, helium, neon, argon, nitrogen and hydrogen.

15. A method of forming a dielectric structure on a surface of a substrate by atomic layer deposition, comprising:
forming a zirconium oxide layer having a first thickness by a flow of a first precursor selected from tetrakisdiethylamino zirconium, zirconium tetrachloride, zirconium tetraiodide, zirconium tertiary-butoxide, zirconium tertiary-methoxide, zirconium tetraisopropoxide and anhydrous zirconium nitrate, by a flow of a purge gas selected from argon, neon, helium, nitrogen and hydrogen, by a flow of a reactant selected from water vapor, oxygen, ozone, hydrogen peroxide, nitrous oxide and alcohol vapor, and by a flow of a purge gas at a substrate temperature of between 300 to 400° C.;
forming a hafnium oxide layer having a second thickness by a flow of a second precursor selected from tetrakisdiethylamino hafnium, hafnium tetrachloride, hafnium tetraiodide, hafnium tertiary-butoxide, hafnium tertiary-methoxide, hafnium tetraisopropoxide and anhydrous hafnium nitrate, by a flow of a purge gas selected from argon, neon, helium, nitrogen and hydrogen, by a flow of a reactant selected from water vapor, oxygen, ozone, hydrogen peroxide, nitrous oxide and alcohol vapor, and by a flow of a purge gas at a substrate temperature of between 300 to 400° C.;
forming a titanium oxide layer having a third thickness by a flow of a third precursor selected from a list including tetrakisdiethylamino titanium, titanium tetra chloride, titanium tetra iodide, titanium tertiary-butoxide, titanium tertiary-methoxide, titanium tetraisopropoxide and anhydrous titanium nitrate, by a flow of a purge gas selected from argon, neon, helium, nitrogen and hydrogen, by a flow of a reactant selected from water vapor, oxygen, ozone, hydrogen peroxide, nitrous oxide and alcohol vapor, and by a flow of a purge gas at a substrate temperature of between 300 to 400° C.; and
forming additional titanium oxide, hafnium oxide, zirconium oxide layers in a preselected order until a preselected thickness is obtained.

16. The method of claim 15, wherein the titanium oxide, hafnium oxide, and zirconium oxide layers are annealed at a temperature of about 500° C. to form an essentially homogenous single layer of Ti_{1-X-Y}Zr_{X}Hf_{Y}O₂.

17. The method of claim 16, wherein the essentially homogeneous single layer is formed to have a crystalline nature, wherein X is selected to range from 0.05 to 0.35, and wherein Y is selected to range from 0.05 to 0.25.

18. The method of claim 17, wherein X is about 0.1, wherein Y is about 0.18, and wherein the layer has a bandgap of about 3.26 eV.

19. The method of claim 17, wherein the homogenous single layer has X and Y values selected to form a ferromagnetic layer.

20. The method of claim 16, wherein the homogenous single layer has X and Y values selected to form an amorphous dielectric layer, having a dielectric constant from 20-30.

21. The method of claim 20, wherein the method includes a substrate formed of a semiconductor material including at least two diffused regions having a first conductivity type separated by a region of a second conductivity type disposed below the dielectric layer.

22. The method of claim 21, wherein the substrate comprises a silicon crystal having a <100> crystal orientation at the surface, and wherein the dielectric layer has X and Y values selected to form a dielectric structure having an equivalent oxide thickness of less than 1.0 nm.

23. The method of claim 22, wherein the X and Y values are selected to form a dielectric layer to form a transistor device.

24. The method of claim 20, wherein the X and Y values are selected to form a dielectric layer having a root mean square surface roughness that is less than one percent of the dielectric layer thickness.

25. A method of forming a wide band gap semiconductor oxide structure on a surface of a substrate by atomic layer deposition, comprising:
forming a titanium zirconium hafnium oxide layer having an approximate formula of Ti_{1-X-Y}Zr_{X}Hf_{Y}O₂ by;
introducing a mixture of titanium tetrachloride having a first flow volume, zirconium tetrachloride having a second flow volume and hafnium tetrachloride having a third flow volume into a vacuum chamber including the substrate at a temperature of from 480 to 540° C. for approximately 0.4 seconds;
introducing a purge gas selected from argon, helium, neon, krypton and nitrogen into the vacuum chamber for approximately 0.5 seconds;
introducing a reactant gas selected from water vapor, oxygen, ozone, nitrous oxide and hydrogen peroxide into the vacuum chamber for 0.5 seconds;
introducing a second purge gas selected from argon, helium, neon and nitrogen into the vacuum chamber for approximately 0.5 seconds; and
repeating until a preselected wide band gap semiconductor oxide layer thickness is obtained.

26. The method of claim 25, wherein the X and Y values are selected to form a wide band gap semiconductor oxide layer having a crystalline nature selected from anatase and rutile, wherein X is selected to range from 0.05 to 0.35, and wherein Y is selected to range from 0.05 to 0.25.

27. The method of claim 25, wherein X is selected to be about 0.1, wherein Y is selected to be about 0.18, and wherein the structure has a bandgap of about 3.26 eV.

28. A method comprising:
forming a dielectric structure including at least zirconium oxide, hafnium oxide and titanium oxide on a surface of a substrate by atomic layer deposition; and
forming a metal layer on the dielectric structure;
wherein the dielectric structure is formed by:
forming a first portion of the dielectric structure, including exposing the substrate surface at a preselected temperature to a first precursor material for a preselected first time period and at a preselected flow volume of the first precursor material to chemically saturate the substrate surface with the first precursor material, forming an absorbed portion of the first precursor material on the substrate surface;
exposing the substrate surface to a preselected volume of a first purge material for a preselected second time period to remove substantially all of a non-absorbed portion of the first precursor material from the substrate surface;
exposing the substrate surface to a preselected volume of a first reactant material for a preselected third time period to react with the absorbed portion of the first precursor material on the substrate surface to form a first dielectric material having a first thickness;
exposing the substrate surface to a preselected volume of a second purge material for a preselected fourth time period to remove substantially all of a non-reacted portion of the first reactant material and a first plurality of gaseous reaction byproducts from the substrate surface;
repeating forming the first portion until a first portion thickness reaches a predetermined first intermediate value;
forming a second portion of the dielectric structure, including exposing the substrate surface to a second precursor material for a preselected fifth time period and at a preselected flow volume of the second precursor material to chemically saturate the substrate surface with the second precursor material, forming an absorbed portion of the second precursor material on the substrate surface;
exposing the substrate surface to a preselected volume of a third purge material for a preselected sixth time period to remove substantially all of a non-absorbed portion of the second precursor material from the substrate surface;
exposing the substrate surface to a preselected volume of a second reactant material for a preselected seventh time period to react with the absorbed portion of the second precursor material on the substrate surface to form a second dielectric material having a second thickness;
exposing the substrate surface to a preselected volume of a fourth purge material for a preselected eighth time period to remove substantially all of a non-reacted portion of the second reactant material and a second plurality of gaseous reaction byproducts from the substrate surface;
repeating forming the second portion until a second portion thickness reaches a predetermined second intermediate value;
forming a third portion of the dielectric structure, including exposing the substrate surface to a third precursor material for a preselected ninth time period and at a preselected flow volume of the third precursor material to chemically saturate the substrate surface with the third precursor material, forming an absorbed portion of the third precursor material on the substrate surface;
exposing the substrate surface to a preselected volume of a fifth purge material for a preselected tenth time period to remove substantially all of a non-absorbed portion of the third precursor material from the substrate surface;
exposing the substrate surface to a preselected volume of a third reactant material for a preselected eleventh time period to react with the absorbed portion of the third precursor material on the substrate surface to form a third dielectric material having a third thickness;
exposing the substrate surface to a preselected volume of a sixth purge material for a preselected twelfth time period to remove substantially all of a non-reacted portion of the third reactant material and a third plurality of gaseous reaction byproducts from the substrate surface;
repeating forming the third portion until a third portion thickness reaches a predetermined third intermediate value; and
repeating the first, second and third forming until a preselected final dielectric layer thickness is obtained.

29. The method of claim 28, wherein the first, second and third portions of the dielectric structure are each selected to have a thickness that is low enough to closely intermingle the portions to effectively form a single layer film having physical properties determined by the ratios of the first, second and third portions of the dielectric layer.

30. The method of claim 28, wherein the dielectric layers are annealed at a temperature greater than 450° C. for a time period sufficient to form a single composite layer having a formula of Ti_{1-X-Y}Zr_{X}Hf_{Y}O₂, an amorphous nature and a dielectric constant greater than 25.

31. A method, comprising:
forming a memory array in a substrate including:
forming at least one dielectric structure by atomic layer deposition containing at least zirconium oxide, hafnium oxide and titanium oxide;
depositing a conductive layer contacting the dielectric layer; and
forming an address decoder in the substrate, the address decoder coupled to the memory array.

32. The method of claim 31, wherein the dielectric structure is formed to have a dielectric constant above 25, and wherein the dielectric layer is formed to have an approximate formula of Ti_{1-X-Y}Zr_{X}Hf_{Y}O₂, wherein X is selected to range from 0.05 to 0.35, and wherein Y is selected to range from 0.05 to 0.25.

33. An electronic device comprising:
an amorphous dielectric structure containing at least one atomic layer deposited dielectric layer including zirconium oxide, hafnium oxide and titanium oxide layers in an integrated circuit; and
a conductive layer contacting the dielectric structure.

34. The electronic device of claim 33, wherein each layer has a surface thickness uniformity that is greater than 0.5% of the layer thickness.

35. The electronic device of claim 33, wherein each layer has a root mean square surface roughness that is less than one percent of the individual layer thickness

36. The electronic device of claim 33, wherein the dielectric structure has a formula of Ti_{1-X-Y}Zr_{X}Hf_{Y}O₂.

37. The electronic device of claim 36, wherein X ranges from 0.05 to 0.35, and wherein Y ranges from 0.05 to 0.25.

38. The electronic device of claim 36, wherein the dielectric structure has a dielectric constant of 25.

39. A system comprising:
a controller;
an electronic device coupled to the controller, wherein the electronic device includes a dielectric structure comprising an atomic layer deposited dielectric layer including at least one of zirconium oxide, hafnium oxide and titanium oxide in an integrated circuit.

40. The system of claim 39, wherein the electronic device includes a memory.

41. A spintronic device comprising:
a crystalline ferromagnetic semiconductor oxide structure containing at least one atomic layer deposited layer of at least one of zirconium oxide, hafnium oxide and titanium oxide; and
a conductive layer contacting the dielectric structure.

42. The spintronic device of claim 41, wherein the crystalline ferromagnetic semiconductor oxide structure has a wide bandgap and is transparent to visible light.

43. The spintronic device of claim 41, wherein each atomic layer deposited layer has a surface thickness uniformity that is greater than 0.5% of the layer thickness root mean square and a surface roughness that is less than one percent of the layer thickness.

44. The spintronic device of claim 41, wherein the crystalline ferromagnetic semiconductor oxide structure has a formula of Ti_{1-X-Y}Zr_{X}Hf_{Y}O₂.

45. The spintronic device of claim 44, wherein X ranges from 0.05 to 0.35, and wherein Y ranges from 0.05 to 0.25.

46. The spintronic device of claim 44, wherein X is 0.1, and wherein Y is 0.18.
